(19) United States
(12) Patent Application Publication
(10) Pub. No.: US 2025/0004380 A1
(43) Pub. Date: Jan. 2, 2025

(54) CONDITIONING SEMICONDUCTOR PROCESSING SOLUTIONS FOR REUSE

(71) Applicant: Intel Corporation, Santa Clara, CA (US)

(72) Inventors: Joseph BLOXHAM, Laveen, AZ (US); Jeremy D. ECTON, Gilbert, AZ (US)

(21) Appl. No.: 18/215,427

(22) Filed: Jun. 28, 2023

(51) Int. Cl. G03F 7/30

(52) U.S. Cl. CPC G03F 7/3092

(57) ABSTRACT

Devices, systems, and methods for conditioning a solvent return flow from a photolithographic process used for semiconductor processing are presented. Reuse of materials in semiconductor processing can provide environmental and manufacturing cost advantages. Devices for conditioning a solvent return flow from a photolithographic process and systems for photolithographic processes include a baffle system and a light system. Methods for reusing a solvent from a photolithographic process include passing the solvent through a conditioning device having a baffle system and a light system.

### FIELD

Descriptions are generally related to semiconductor processing, and more particular descriptions are related to equipment and methods for managing the reuse of solvents for lithographic processes, and devices, systems, and methods for conditioning lithographic solvents for reuse.

### BACKGROUND

Semiconductor chips (integrated circuit (IC) chips or dies) are central to intelligent devices and systems, such as personal computers, laptops, tablets, phones, servers, and other consumer and industrial products and systems. Manufacturing semiconductor chips presents a number of challenges and these challenges are amplified as devices become smaller and performance demands increase. Challenges include, for example, unwanted material interactions, precision and scaling requirements, power delivery requirements, limited failure tolerance, and material and manufacturing costs.

In semiconductor manufacturing, it is important to be able to create extremely small features accurately and reproducibly. Optical lithography (photolithography) is one process used in the semiconductor manufacturing industry to create features on IC chips. In optical lithography, light is used to pattern a layer of photosensitive material on a wafer surface. The light sensitive material is, for example, a photoresist. To pattern the photoresist, a mask (also called a photomask, lithographic photomask, or a lithographic mask) is used as a template to create a light pattern which exposes only a portion of the photoresist and creates developed and undeveloped regions according to the mask pattern. Depending on the type of photoresist selected, a subsequent process such as exposing the patterned surface to a solvent, removes either the exposed (developed) or the unexposed (undeveloped) sections of the photoresist from the surface of the chip being manufactured. The patterned photoresist can then be used as a template to, for example, deposit materials onto or etch the surface of a wafer or panel in locations specified by the template. After the deposition of further materials, etching, and/or other processes, the remaining photoresist is typically removed from the surface in a stripping process.

### BRIEF DESCRIPTION OF THE DRAWINGS

The figures are provided to aid in understanding the invention. The figures can include diagrams and illustrations of exemplary devices, structures, assemblies, data, methods, and systems. For ease of explanation and understanding, these devices, structures, assemblies, data, methods, and systems, the figures are not an exhaustively detailed description. The figures therefore should not be understood to depict the entire metes and bounds of structures, assemblies, data, methods, and systems possible without departing from the scope of the invention.

FIG. 1 shows an exemplary baffle assembly for conditioning the return flow from a photolithographic process.

FIG. 2 provides an additional exemplary baffle assembly for conditioning the return flow from a photolithographic process.

FIG. 3 illustrates a further exemplary baffle assembly for conditioning the return flow from a photolithographic process.

FIG. 4 illustrates another exemplary baffle assembly for conditioning the return flow from a photolithographic process.

FIG. 5 shows an additional exemplary baffle assembly for conditioning the return flow from a photolithographic process.

FIG. 6 provides a further exemplary baffle assembly for conditioning the return flow from a photolithographic process.

FIGS. 7A-7B show an alternate view of the exemplary baffle-containing devices of FIGS. 1-6.

FIG. 8 illustrates a system for managing the return of solvent to a photolithographic process chamber.

FIG. 9 provides a diagram for a method of managing a solvent return flow from a photolithography process.

FIG. 10 shows an exemplary computing system that provides optional computing resources for a system for managing the return solvent flow for a photolithographic process.

Descriptions of certain details and implementations follow, including non-limiting descriptions of the figures, which depict non-limiting examples and implementations.

### DETAILED DESCRIPTION

References to one or more examples are to be understood as describing a particular feature, structure, or characteristic included in at least one implementation of the invention. The phrase “one example” or “an example” are not necessarily all referring to the same example or embodiment. Any aspect described herein can potentially be combined with any other aspect or similar aspect described herein, regardless of whether the aspects are described with respect to the same figure or element.

The words “connected” and/or “coupled” can indicate that two or more elements are in direct physical or electrical contact with each other. The term “coupled,” however, can also mean that two or more elements are not in direct contact with each other and are instead separated by one or more elements but they may still co-operate or interact with each other, for example, physically, magnetically, or electrically.

The words “first,” “second,” and the like, do not indicate order, quantity, or importance, but rather are used to distinguish one element from another. The words “a” and “an” herein do not indicate a limitation of quantity, but rather denote the presence of at least one of the referenced items. The terms “follow” or “after” can indicate immediately following or following after some other event or events. Other sequences of operations can also be performed according to alternative embodiments. Furthermore, additional operations may be added or removed depending on the particular application.

Disjunctive language such as the phrase “at least one of X, Y, or Z,” is used in general to indicate that an element or feature, may be either X, Y, or Z, or any combination thereof (e.g., X, Y, and/or Z). Thus, this disjunctive language should be understood not to imply that certain embodiments require at least one of X, at least one of Y, or at least one of Z to each be present.

Terms such as chip, die, IC chip, IC die, semiconductor IC, or semiconductor chip are used interchangeably and refer to a semiconductor device comprising integrated circuits. Chips are manufactured in wafer form where a wafer contains a number of chips. After manufacture, the wafer is diced apart to create chips.

Flow diagrams as illustrated herein provide examples of sequences of various process actions. The flow diagrams can indicate operations to be executed by a software or firmware routine, as well as physical operations. Although shown in a particular sequence or order, unless otherwise specified, the order of the actions can be modified. Thus, the illustrated diagrams should be understood only as examples, and the process can be performed in a different order, and some actions can be performed in parallel. Additionally, one or more actions can be omitted and not all implementations will perform all actions.

Various components described can be a means for performing the operations or functions described. Each component described includes software, hardware, or a combination of these. The components can be implemented as software modules, hardware modules, special-purpose hardware (for example, application specific hardware, application specific integrated circuits (ASICs), digital signal processors (DSPs), etc.), embedded controllers, or hardwired circuitry).

To the extent various computer operations or functions are described herein, they can be described or defined as software code, instructions, configuration, and/or data. The software content can be provided via an article of manufacture with the content stored thereon, or via a method of operating a communication interface to send data via the communication interface. A machine-readable storage medium can cause a machine to perform the functions or operations described, and includes any mechanism that stores information in a tangible form accessible by a machine (e.g., computing device), such as recordable/non-recordable media (e.g., read only memory (ROM), random access memory (RAM), magnetic disk storage media, optical storage media, flash memory devices). A communication interface includes any mechanism that interfaces to, for example, a hardwired, wireless, or optical medium to communicate to another device, such as, for example, a memory bus interface, a processor bus interface, an Internet connection, a disk controller.

Reuse or recycling of a solvent flow from a photolithographic process provides environmental and cost advantages. Photolithographic processes in where photoresist is removed from a surface include, for example, stripping processes where photoresist is completely removed from a surface, and patterning processes where photoresist is removed in selected regions. In an example photolithographic patterning process, dry film photoresist (DFR) is laminated on panels and is patterned by exposing selected regions through a mask to UV (ultraviolet) light. Other photoresists are also possible and the substrate can be a panel or a wafer, for example. The DFR in unwanted (unexposed) regions is then removed by spraying or immersing the panel in a development solution. In this photolithographic example where DFR has been used, DFR is a negative resist in which regions unexposed to light remain soluble in the development solvent. UV light exposure initiates a chemical reaction in which monomeric species polymerize and become insoluble to the development chemistry. The resulting patterned DFR surface is used as a guide for depositing copper or other materials, for example. After further processing, where copper or other materials are deposited, the DFR is typically removed, or stripped, from the surface using a solvent.

The return flow from a photolithographic patterning or stripping process can include solvent that was used to remove unwanted photoresist from a patterned surface. In the above DFR example, the return solvent stream can contain DFR that continues to react after removal from the photolithographic process chamber. The return flow that is part of a development or stripping process can contain some photoresist as it flows back into a holding tank. There are often filters to remove larger pieces of DFR from the returning liquid return flow, but smaller pieces can enter the solvent holding tank and continue to react with bath chemistry. The continued reaction with bath chemistry reduces bath life by consuming the active bath ingredients. This continued reaction also produces unwanted chemical species that can interfere with subsequent semiconductor processing steps when the development solvent is reused. Even extremely small impurities in the manufacturing process can be enough to result in an entire semiconductor IC device being inoperable.

Photolithographic processes can involve the use of a positive or a negative resist. A negative resist example has been discussed in the preceding paragraph. A positive photoresist is one that becomes more soluble in the regions that are exposed to light. A mask is used to create a light pattern on the surface of one or more devices being manufactured (in a wafer or panel format, for example). A solvent is used to remove the positive photoresist in exposed regions to create a physical pattern on the device surface. The patterned surface is used to create features in further semiconductor manufacturing processes. The solvent return flow can contain small particles of photoresist that evade filters and continue to react. This continued chemical reaction interferes with solvent reuse and reduces the useful life of the solvent. Embodiments of the present invention are useful for a variety of different photolithographic solvent return flows and are not limited to the chemistry discussed here for explanation.

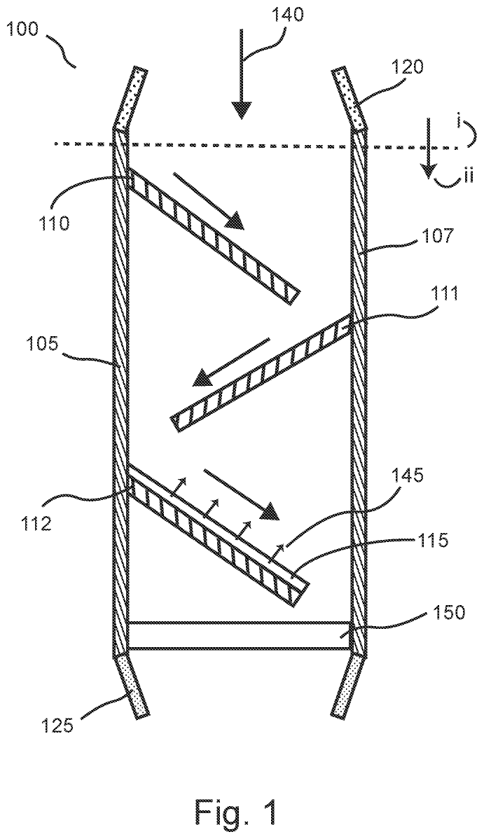

FIG. 1 illustrates an exemplary photolithographic return flow conditioning device 100 for solvent from a photolithographic development chamber (not shown here) or stripping chamber (not shown). The return flow conditioning device 100 includes side walls 105 and 107, baffles 110, 111, and 112 and planar light source 115. Depending on the device 100 footprint, side walls 105 and 107 can be the same or different. Side walls 105 and 107 are elements of an enclosure for guiding a solvent flow. Planar light source 115 can be, for example, a UV light source having a wavelength between and including 10 nanometers to 400 nanometers, a white light source having a wavelength of 400 nanometers to 780 nanometers, or a combination UV and white light source. Solvent flow arrows 140 indicate the direction of flow for the solvent returning from a photolithographic development chamber. Light direction arrows 145 indicate a direction that light is being emitted from planar light source 115. Baffles 110 and 111 shield a photolithographic development chamber from unwanted light created by planar light source 115. Baffle 112 houses planar light source 115. Extraneous light in a photolithographic development chamber can lead to a resulting device that fails because its features have not been created with adequate accuracy. The wide surface areas of the baffles 110 and 111 and planar light source 115 allows laminar flow of return solvent from the photolithographic development chamber across planar light source 115. For example, the baffles can have dimensions from 50 mm to 500 mm. Other dimensions are also possible. Laminar flow over the planar surface of the light source 115 can enhance the rate of reaction of unwanted reactive species. Reacted photoresist that has formed large enough particles can be removed from the return flow by filtration, for example. Photolithographic return flow conditioning device 100 includes an optional filtration device 150 placed after baffle 112 in the return flow stream that is capable of filtering particles reacted species created by the flow of return solvent over light source 115. The filter can be, for example, a conventional mesh, a centrifugal filter, and/or a cyclone filter. The filtering can occur between the photolithographic return flow conditioning device 100 and a solvent tank (not shown) or filtering can occur in the solvent tank, such as, for example, through continuous filtering. Photolithographic return flow conditioning device 100 additionally includes connector 120 for connecting the device to a photolithographic development chamber solvent egress system and connector 125 for connecting the device to a photolithographic solvent return system.

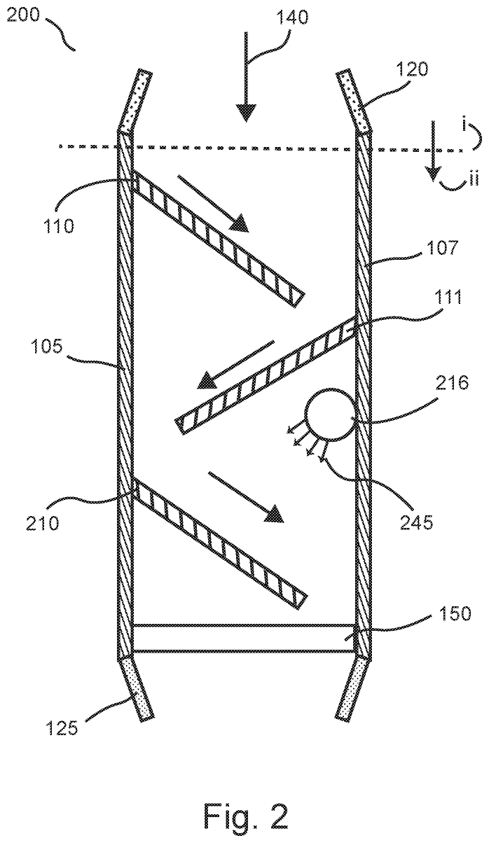

FIGS. 2-6 show further examples of a photolithographic return flow conditioning devices for solvent from a photolithographic development or stripping chamber (not shown). The elements of FIGS. 2-6 are similar to ones discussed with respect to FIG. 1, except as renumbered and described below. In FIG. 2, the return flow conditioning device 200 includes side walls 105 and 107, baffles 110, 111 and 210, and light source 216. In FIG. 2, the light source 216 is attached to a sidewall 107 and light from the light source is incident on the surface of baffle 210. Light source 216 can be, for example, a UV light source having a wavelength between and including 10 nanometers to 400 nanometers, a white light source having a wavelength of 400 nanometers to 780 nanometers or a combination UV and white light source. In this example, the light source 216 is not necessarily a planar light source, although it could be. Light source 216 is placed so that light emitted is incident onto the surface of baffle 210. Light direction arrows 245 indicate a direction that light is being emitted from light source 216.

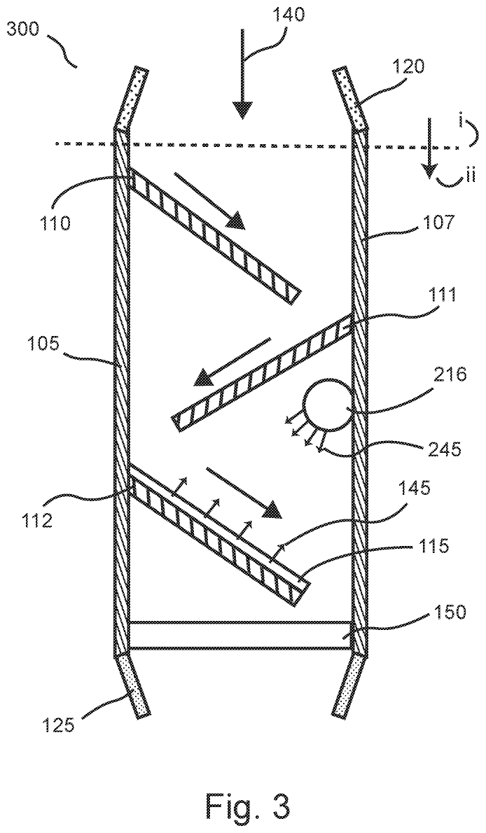

FIG. 3 includes features of both FIG. 1 and FIG. 2. In FIG. 3 the return flow conditioning device 300 includes a planar light source 115 on baffle 112 and a light source 216 housed on sidewall 107.

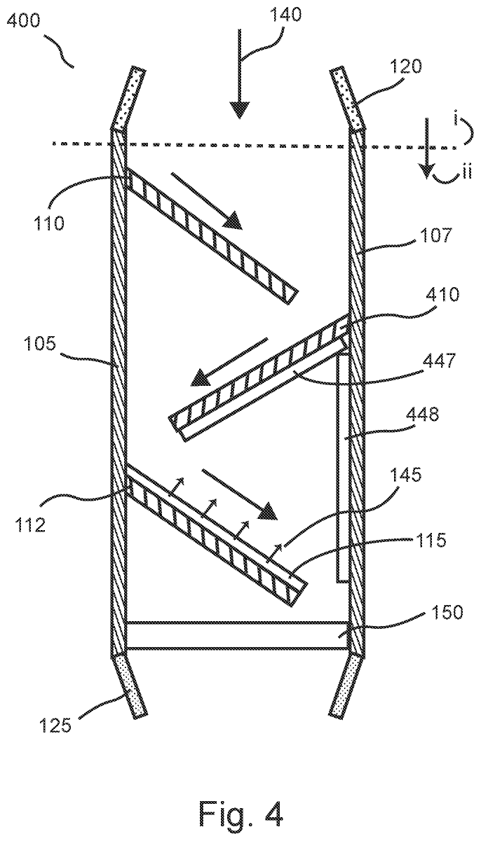

FIG. 4 illustrates an exemplary photolithographic return flow conditioning device 400 that is similar to the device shown in FIG. 1. The photolithographic return flow conditioning device 400 includes baffles 110, 112, and 410 and additionally includes mirrors 447 and 448. Mirror 447 is attached to a side of baffle 410 that is opposite the solvent flow side of baffle 410. Mirror 448 is attached to sidewall 107. Mirrors 447 and 448 are positioned so that at least some of the light emitted from planar light source 115 is reflected back toward the light source 115. Mirrors 447 and 448 can increase the light intensity incident upon solvent that flows over the surface of light source 115. The mirroring of the interior of photolithographic return flow conditioning device 400 can include all the mirroring shown, smaller mirrors, or only one of the mirrors 447 and 448. Additionally, the mirrors can be placed to have different angles of reflection.

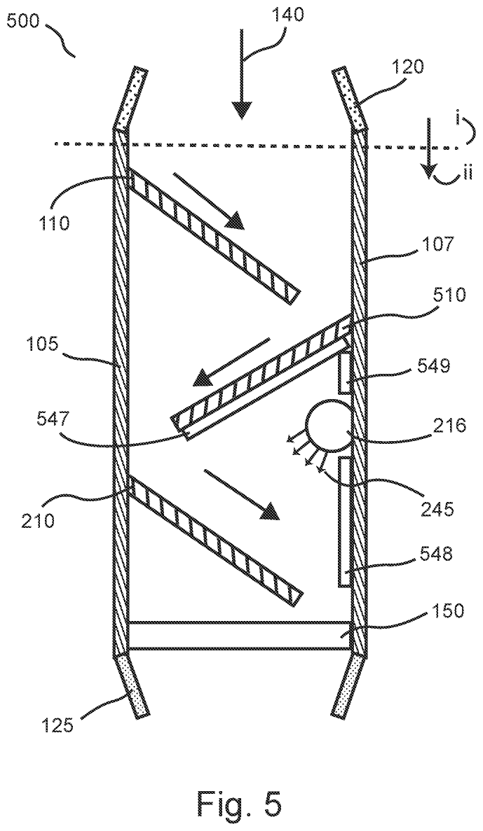

FIG. 5 shows an additional exemplary photolithographic return flow conditioning device 500 that is similar to the device shown in FIG. 2. The photolithographic return flow conditioning device 500 includes baffles 110, 210, and 510 and additionally includes mirrors 547, 548, and 549. Mirror 547 is attached to a side of baffle 510 that is opposite the solvent flow side of baffle 510. Mirrors 548 and 549 are attached to sidewall 107. Light source 216 is positioned between mirrors 548 and 549. Mirrors 547, 548, and 549 are positioned so that at least some of the light emitted from light source 216 is reflected back toward the surface of baffle 210. Mirrors 547, 548, and 549 can increase the intensity of the light incident upon solvent that flows over the surface of baffle 210. The mirroring of the interior of photolithographic return flow conditioning device 500 can include all the mirroring shown, smaller mirrors, or only one or only 2 of the mirrors 547, 548, and 549. Additionally, the mirrors can be placed to have different angles of reflection.

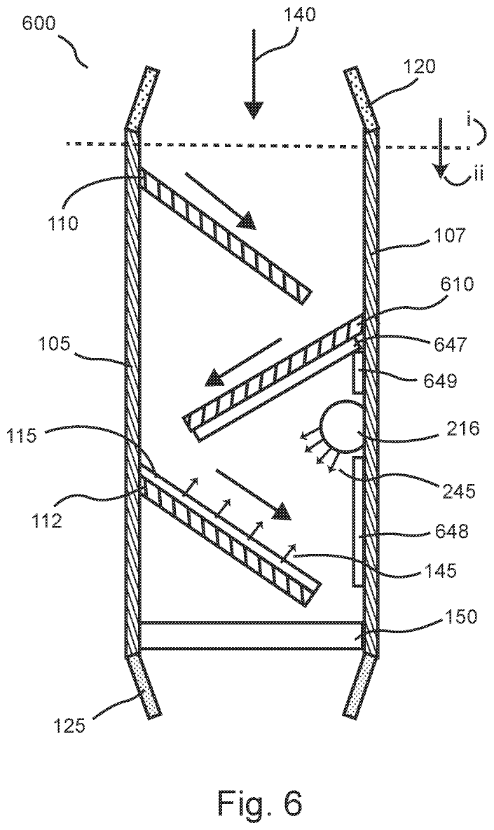

FIG. 6 provides a further exemplary photolithographic return flow conditioning device 500 that is similar to the device shown in FIG. 3. The photolithographic return flow conditioning device 600 includes baffles 110, 112, and 610 and additionally includes mirrors 647, 648, and 649. Mirror 647 is attached to a side of baffle 610 that is opposite the solvent flow side of baffle 610. Mirrors 648 and 649 are attached to sidewall 107. Light source 216 is positioned between mirrors 648 and 649. Mirrors 647, 648, and 649 are positioned so that at least some of the light emitted from light source 216 and planar light source 115 is reflected back toward the surface of planar light source 115. Mirrors 647, 648, and 649 can increase the intensity of light incident upon solvent that flows over the surface of planar light source 115. The mirroring of the interior of photolithographic return flow conditioning device 600 can include all the mirroring shown, smaller mirrors, or only one or only 2 of the mirrors 647, 648, and 649. Additionally, the mirrors can be placed to have different angles of reflection.

Although three baffles 110 are shown in FIGS. 1-6, other numbers of baffles are possible. Such as, for example, two, four, five, six, or more baffles.

Devices in FIGS. 1-6 are shown without a particular orientation specified. If an exemplary device of FIGS. 1-6 is not oriented so that return solvent flows through the device by gravity, a pump (not shown) can be used to cause the return solvent to flow through the device. A pump can also be used in conjunction with gravity flow.

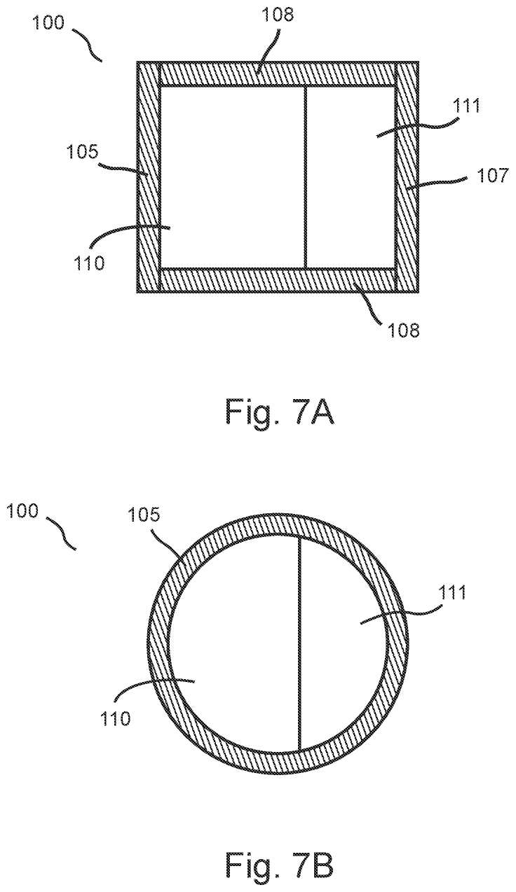

FIGS. 7A-7B illustrate two different exemplary potential cutaway rotated perspective views of devices shown in FIGS. 1-6 taken along dashed line “i” looking in the direction of arrow “ii.” In FIG. 7A, taking FIG. 1 as the reference figure, device 100 (or for FIGS. 2-6, device 200, 300, 400, 500, or 600, respectively), includes side walls 105, 107, and 108. Side walls 105, 107, and 108, can be the same or different in size, shape, and material composition. The side walls 105 and 107 form an enclosure for guiding solvent flow and protecting the solvent from the ambient atmosphere. From this view, baffles 110 and 111 (or for FIGS. 4-6, baffles 410, 510, and 610 respectively) are visible. Although a rectangular shape is shown for the footprint of sidewalls 105 and 107, other shapes and numbers of walls are possible, such as, for example, squares, triangles having three sides, pentagons having five sides, etc.

FIG. 7B shows a different possible exemplary footprint for the devices described herein and according to FIGS. 1-6. In FIG. 7B, the sidewall 105 is continuous and sidewalls 105 and 107 are the same. The side wall 105 forms an enclosure for guiding solvent flow and protecting the solvent from the ambient atmosphere. Side wall 105 is shown as having a circular footprint, but could also, for example, have an oval footprint. Baffles, mirrors (448, 549, 548, 649, 648), and light sources (216) are attached to continuous sidewall 105 although they are not visible in this view. From this view, baffles 110 and 111 (or for FIGS. 4-6, baffles 410, 510, and 610 respectively) are again visible.

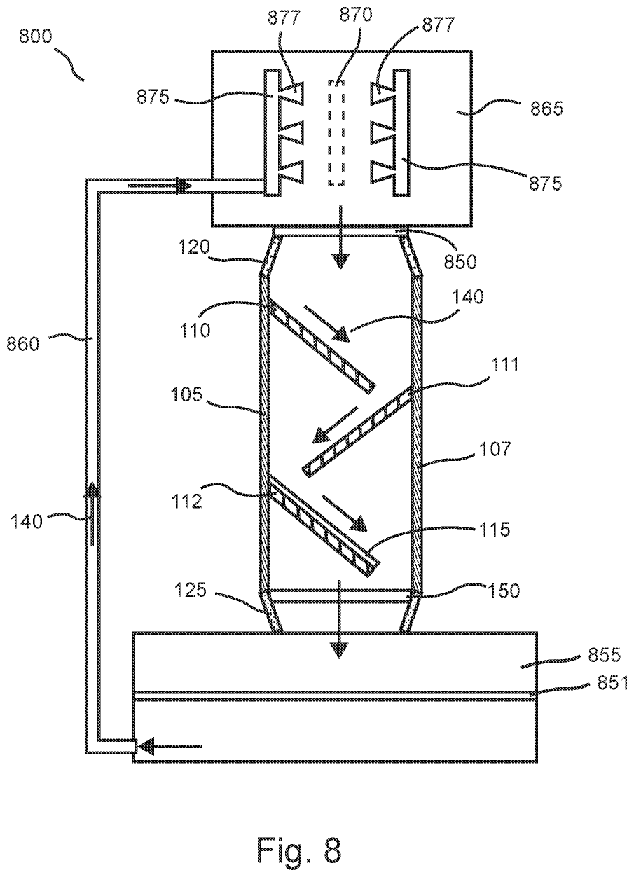

FIG. 8 provides a schematic of a photolithographic return flow conditioning device that is integrated into an exemplary photolithography process system 800. The photolithography process system 800 is useful for removing unwanted photoresist from a substrate 870 that has a patterned photoresist on at least one surface. The photolithography process system 800 includes an exemplary photolithographic return flow conditioning device that is similar to the device of FIG. 1, however, any of the devices described herein and according to FIGS. 1-7 can be used in a similar manner in the photolithography process system 800. The photolithography process system 800 additionally includes a solvent tank 855, a solvent return system 860, and a filtration system that includes filtration devices 150, 850, and 851. Filtration devices 150, 850, and 851 are each optional and one or more can be installed in a different location within the system. Additionally, the system can have additional filtration devices (not shown). For example, the solvent flow exiting the photolithographic return flow conditioning device can be directed into a separate filtration unit, such as, for example, a centrifugal filter or a cyclone filter. Photolithography process system 800 further includes a process development (or stripping) chamber 865 which includes a solvent sprayer system comprising spray manifolds 875 and spray nozzles 877. Different configurations from the ones illustrated are possible. For example, photolithographic process development (or stripping) chamber could be an immersion chamber in which the substrate 870 is immersed in solvent. Additionally, although the photolithographic return flow conditioning device is shown directly connected to process development (or stripping) chamber 865 and solvent tank 855, there could be other connections and adaptors present. Additionally, system 800 includes systems for adding solvent or draining solvent (not shown). Further, the photolithographic process system 800 can also optionally include pumps, heating and cooling elements, devices that monitor solvent health, such as spectrophotometric devices, and intelligence (a computing system) to automate aspects of the process. Intelligence can, for example, monitor the condition of the solvent and drain and replace some or all of the solvent or alert a user to a need for maintenance. Intelligence can also monitor the temperature of the solvent, compare the measured temperature to a set point, and adjust the temperature up or down with the heating and cooling elements.

The exemplary photolithographic return flow conditioning device of FIG. 8 includes side walls 105 and 107, baffles 110, 111, and 112 and planar light source 115. Depending on the device 100 footprint, side walls 105 and 107 can be the same or different. Planar light source 115 can be, for example, a UV light source having a wavelength between and including 10 nanometers to 400 nanometers, a white light source having a wavelength of 400 nanometers to 780 nanometers, or a combination UV and white light source. Solvent flow arrows 140 indicate the direction of flow for the solvent returning from a photolithographic development chamber. Baffle 112 houses planar light source 115. The photolithographic return flow conditioning device additionally includes connector 120 for connecting the device to a photolithographic development chamber 865 solvent egress system and connector 125 for connecting the device to a solvent tank 855.

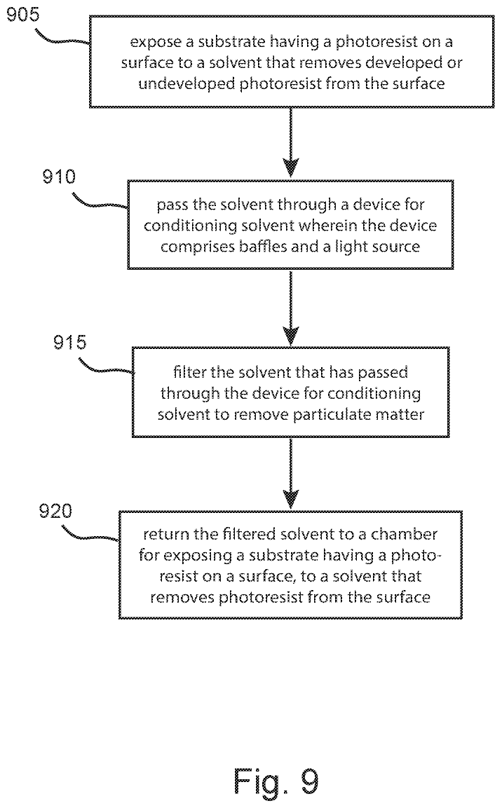

FIG. 9 diagrams a process for conditioning a solvent from a photolithographic process chamber. A substrate having a photoresist on a surface is exposed to a solvent that removes developed or undeveloped regions of the photoresist 905. The process can be a photoresist development or stripping process. A photoresist can be a negative photoresist or a positive photoresist. For a positive photoresist and a development process, the solvent removes the regions of the photoresist that have been exposed to light and for a negative photoresist, the solvent removes the regions that have not been exposed to light. For a stripping process, the solvent removes the remaining photoresist. The solvent exiting the photolithographic development chamber can be filtered to remove particulate matter before entering the device for conditioning solvent. The solvent from the development chamber is passed through a device for conditioning the solvent for return to the process chamber 910. The device for conditioning the solvent is a device, such as, for example, a device described herein and diagrammed in FIGS. 1-7. The solvent is filtered to remove particulate matter 915 before returning it to a chamber for removing photoresist from a substrate surface 920. The solvent may also reside in a holding tank before returning to a chamber for removing photoresist from a substrate surface. The solvent can be filtered 915 while in the holding tank. This filtration can be a continuous filtration process. Additionally, the solvent may be heated or cooled during the process of FIG. 9.

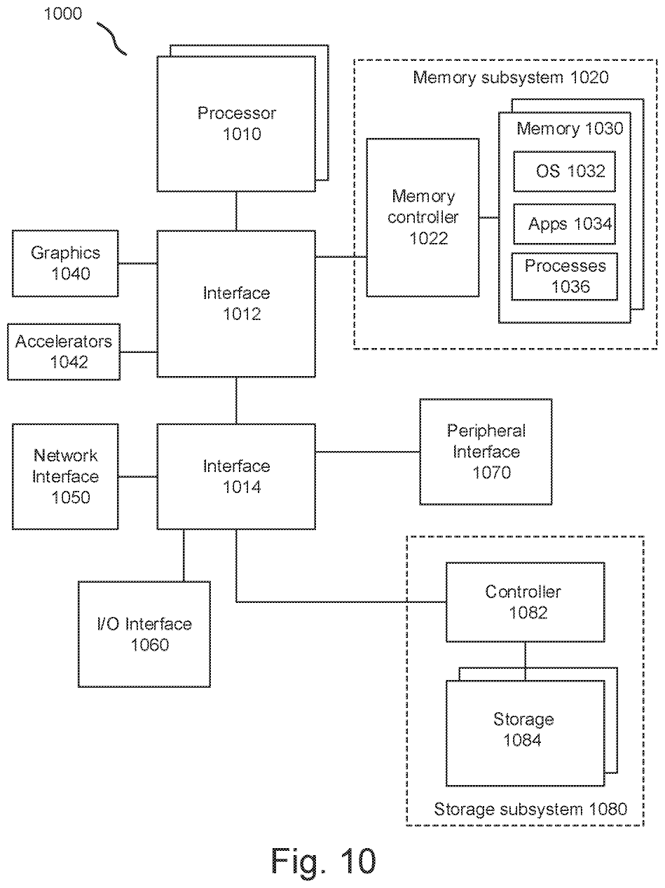

FIG. 10 depicts an example computing system which can optionally be used to manage aspects of a photolithographic process system. The computing system can be a system used for running equipment in a semiconductor fabrication plant. Not all elements of the system of FIG. 10 may be necessary for a particular application. For example, instructions for operating photolithographic process system, or for performing one or more aspects of the processes described herein be stored and/or run on the computing system. In this example, the system is communicatively coupled to one or more photolithographic process systems and can manage, for example, solvent health, pumps, process times, and/or process temperatures. The computing system employed can include more, different, or fewer features than the one described with respect to FIG. 10.

Computing system 1000 includes processor 1010, which provides processing, operation management, and execution of instructions for system 1000. Processor 1010 can include any type of microprocessor, CPU (central processing unit), GPU (graphics processing unit), processing core, or other processing hardware to provide processing for system 1000, or a combination of processors or processing cores. Processor 1010 controls the overall operation of system 1000, and can be or include, one or more programmable general-purpose or special-purpose microprocessors, DSPs, programmable controllers, ASICs, programmable logic devices (PLDs), or the like, or a combination of such devices.

In one example, system 1000 includes interface 1012 coupled to processor 1010, which can represent a higher speed interface or a high throughput interface for system components needing higher bandwidth connections, such as memory subsystem 1020 or graphics interface components 1040, and/or accelerators 1042. Interface 1012 represents an interface circuit, which can be a standalone component or integrated onto a processor die. Where present, graphics interface 1040 interfaces to graphics components for providing a visual display to a user of system 1000. In one example, the display can include a touchscreen display.

Accelerators 1042 can be a fixed function or programmable offload engine that can be accessed or used by a processor 1010. For example, an accelerator among accelerators 1042 can provide data compression (DC) capability, cryptography services such as public key encryption (PKE), cipher, hash/authentication capabilities, decryption, or other capabilities or services. In some cases, accelerators 1042 can be integrated into a CPU socket (e.g., a connector to a motherboard (or circuit board, printed circuit board, mainboard, system board, or logic board) that includes a CPU and provides an electrical interface with the CPU). For example, accelerators 1042 can include a single or multi-core processor, graphics processing unit, logical execution unit single or multi-level cache, functional units usable to independently execute programs or threads, application specific integrated circuits (ASICs), neural network processors (NNPs), programmable control logic, and programmable processing elements such as field programmable gate arrays (FPGAs) or programmable logic devices (PLDs). Accelerators 1042 can provide multiple neural networks, CPUs, processor cores, general purpose graphics processing units, or graphics processing units can be made available for use by artificial intelligence (Al) or machine learning (ML) models.

Memory subsystem 1020 represents the main memory of system 1000 and provides storage for code to be executed by processor 1010, or data values to be used in executing a routine. Memory subsystem 1020 can include one or more memory devices 1030 such as read-only memory (ROM), flash memory, one or more varieties of random access memory (RAM) such as static RAM (SRAM), dynamic RAM (DRAM), synchronous DRAM (SDRAM) and/or or other memory devices, or a combination of such devices. Memory 1030 stores and hosts, among other things, operating system (OS) 1032 to provide a software platform for execution of instructions in system 1000, and stores and hosts applications 1034 and processes 1036. In one example, memory subsystem 1020 includes memory controller 1022, which is a memory controller to generate and issue commands to memory 1030. The memory controller 1022 could be a physical part of processor 1010 or a physical part of interface 1012. For example, memory controller 1022 can be an integrated memory controller, integrated onto a circuit within processor 1010.

System 1000 can also optionally include one or more buses or bus systems between devices, such memory buses, graphics buses, and/or interface buses. Buses or other signal lines can communicatively or electrically couple components together, or both communicatively and electrically couple the components. Buses can include physical communication lines, point-to-point connections, bridges, adapters, controllers, or other circuitry or a combination. Buses can include, for example, one or more of a system bus, a peripheral component interconnect (PCI) or PCIe (PCI express) bus, a Hyper Transport or industry standard architecture (ISA) bus, a small computer system interface (SCSI) bus, a USB (universal serial bus), or a Firewire bus.

In one example, system 1000 includes interface 1014, which can be coupled to interface 1012. In one example, interface 1014 represents an interface circuit, which can include standalone components and integrated circuitry. In one example, user interface components or peripheral components, or both, couple to interface 1014. Network interface 1050 provides system 1000 the ability to communicate with remote devices (e.g., servers or other computing devices) over one or more networks. Network interface 1050 can include an Ethernet adapter, wireless interconnection components, cellular network interconnection components, USB, or other wired or wireless standards-based or proprietary interfaces. Network interface 1050 can transmit data to a device that is in the same data center or rack or a remote device, which can include sending data stored in memory.

Some examples of network interface 1050 are part of an infrastructure processing unit (IPU) or data processing unit (DPU), or used by an IPU or DPU. An xPU can refer at least to an IPU, DPU, GPU, GPGPU (general purpose computing on graphics processing units), or other processing units (e.g., accelerator devices). An IPU or DPU can include a network interface with one or more programmable pipelines or fixed function processors to perform offload of operations that could have been performed by a CPU. The IPU or DPU can include one or more memory devices.

In one example, system 1000 includes one or more input/output (I/O) interface(s) 1060. I/O interface 1060 can include one or more interface components through which a user interacts with system 1000 (e.g., audio, alphanumeric, tactile/touch, or other interfacing). Peripheral interface 1070 can include additional types of hardware interfaces, such as, for example, interfaces to semiconductor fabrication equipment and/or electrostatic charge management devices.

In one example, system 1000 includes storage subsystem 1080. Storage subsystem 1080 includes storage device(s) 1084, which can be or include any conventional medium for storing data in a nonvolatile manner, such as one or more magnetic, solid state, and/or optical based disks. Storage 1084 can be generically considered to be a “memory,” although memory 1030 is typically the executing or operating memory to provide instructions to processor 1010. Whereas storage 1084 is nonvolatile, memory 1030 can include volatile memory (e.g., the value or state of the data is indeterminate if power is interrupted to system 1000). In one example, storage subsystem 1080 includes controller 1082 to interface with storage 1084. In one example controller 1082 is a physical part of interface 1012 or processor 1010 or can include circuits or logic in both processor 1010 and interface 1014.

A power source (not depicted) provides power to the components of system 1000. More specifically, power source typically interfaces to one or multiple power supplies in system 1000 to provide power to the components of system 1000.

Exemplary systems may be implemented in various types of computing, smart phones, tablets, personal computers, and networking equipment, such as switches, routers, racks, and blade servers such as those employed in a data center and/or server farm environment.

Besides what is described herein, various modifications can be made to what is disclosed and implementations of the invention without departing from their scope. Therefore, the illustrations and examples herein should be construed in an illustrative, and not a restrictive sense. The scope of the invention should be measured solely by reference to the claims that follow.

What is claimed is:

1. A device for a return solvent flow comprising:
an enclosure having an ingress and an egress for solvent;
at least two baffles within the enclosure;
a light source within the enclosure wherein a first baffle of the at least two baffles is between the ingress of the enclosure and the light source; and
a connector for connecting to a photolithographic process system wherein the connector is proximate to the ingress of the enclosure.

2. The device of claim 1 wherein the light source is a UV light source.

3. The device of claim 1 wherein the light source is a planar UV light source.

4. The device of claim 1 wherein the light source is a planar UV light source located on a surface of a second baffle of the at least two baffles.

5. The device of claim 1 wherein the light source is located on a side wall of the enclosure.

6. The device of claim 1 also including at least one mirror within the enclosure wherein the first baffle of the at least two baffles is between the mirror and the ingress of the enclosure.

7. The device of claim 1 including at least three baffles within the enclosure and wherein two of the at least three baffles are located between the ingress of the enclosure and the light source.

8. A system for a photolithographic process comprising:
a photolithographic process chamber for removing photoresist from a substrate;
a solvent tank;
a solvent delivery system wherein the solvent delivery system is capable of sending solvent from the solvent tank to the process chamber; and
a device for conditioning solvent for return to the photolithographic process chamber comprising:
an enclosure for guiding solvent flow having an ingress and egress for solvent;
at least two baffles within the enclosure;
a light source within the enclosure wherein a first baffle of the at least two baffles is between the ingress of the enclosure and the light source; and
a connector for connecting to a photolithographic process system wherein the connector is proximate to the ingress of the enclosure;
wherein the ingress of the device for conditioning solvent for return to the photolithographic process chamber is coupled to and capable of receiving solvent from the photolithographic process chamber, and
wherein the egress of the device for conditioning solvent is coupled to and capable of allowing solvent to enter the solvent tank.

9. The system of claim 8 wherein the light source is a UV light source.

10. The system of claim 8 wherein the light source is a planar UV light source.

11. The system of claim 8 wherein the light source is a planar UV light source located on a surface of a second baffle of the at least two baffles.

12. The system of claim 8 wherein the light source is located on a side wall of the enclosure.

13. The system of claim 8 also including at least one mirror within the enclosure wherein the first baffle of the at least two baffles is between the mirror and the ingress of the enclosure.

14. The system of claim 8 including three baffles within the enclosure and wherein two of the three baffles are located between the ingress of the enclosure and the light source.

15. The system of claim 8 also including a filter system between the device for conditioning solvent for return and the solvent delivery system.

16. A method for conditioning a solvent for reuse in a photolithographic process comprising:
exposing a substrate having a patterned photoresist on a surface to a solvent so that the solvent removes developed or undeveloped regions of the photoresist;
passing the solvent through a device for conditioning solvent wherein the device for conditioning solvent comprises at least two baffles and a light source wherein a first of the at least two baffles is between an ingress for solvent for the device and the light source;
filtering the solvent that has passed through the device for conditioning solvent to remove particulate matter; and
returning the filtered solvent to a chamber for exposing a substrate having a patterned photoresist on a surface, to a solvent.

17. The method of claim 16 also comprising filtering the solvent to remove particulate matter before passing the solvent through a device for conditioning solvent.

18. The method of claim 16 wherein the device for conditioning solvent comprises three baffles and wherein two of the three baffles are located between the ingress and the light source.

19. The method of claim 16 wherein the light source is a planar UV light source.

20. The method of claim 16 wherein the light source is a planar light source that is located on a surface of a second of the at least two baffles.
